(19) United States
(12) Patent Application Publication
(10) Pub. No.: US 2019/0378915 A1
(43) Pub. Date: Dec. 12, 2019

(54) FORMING NANOSHEET TRANSISTOR WITH INNER SPACERS AT HIGHLY SCALED GATE PITCH

(71) Applicant: International Business Machines Corporation, Armonk, NY (US)

(72) Inventors: Julien Frougier, Albany, NY (US); Kangguo Cheng, Schenectady, NY (US); NICOLAS LOUBET, Guilderland, NY (US)

(73) Assignee: International Business Machines Corporation, Armonk, NY (US)

(21) Appl. No.: 16/006,142

(22) Filed: Jun. 12, 2018

(51) Int. Cl. H01L 29/66; H01L 21/02; H01L 21/311; H01L 29/06; H01L 29/423; H01L 29/786

(52) U.S. Cl. CPC H01L 29/66553; H01L 21/02603; H01L 21/02532; H01L 21/02236; H01L 21/31111; H01L 29/78696; H01L 29/66742; H01L 29/0673; H01L 29/42392; H01L 29/78651; H01L 29/66545

(57) ABSTRACT

A nanosheet transistor includes a nanosheet stack having a plurality of nanosheet layers and a plurality of gate material layers stacked upon a substrate. The nanosheet stack further includes a first fin and a second fin, and at least one gate formed on the nanosheet stack. The transistor further includes at least one inner spacer disposed on at least one sidewall of the gate material layers and the at least one gate. The at least one inner spacer is formed of an oxide layer in which a thicker layer of the oxide layer is deposited on the sidewalls of the at least one gate and the gate material layers than a thickness of the oxide layer deposited on sidewalls the nanosheet layers. The transistor further includes at least one outer spacer formed on the at least one inner spacer. The at least one outer spacer is formed of a spacer dielectric material.

### TECHNICAL FIELD

The present invention relates generally to a method for fabricating nanosheet transistors and a structure formed by the method. More particularly, the present invention relates to a method for fabricating nanosheet transistors with inner spacers at highly scaled gate pitch and a structure formed by the method.

### BACKGROUND

An integrated circuit (IC) is an electronic circuit formed using a semiconductor material, such as Silicon, as a substrate and by adding impurities to form solid-state electronic devices, such as transistors, diodes, capacitors, and resistors. Commonly known as a “chip” or a “package”, an integrated circuit is generally encased in hard plastic, forming a “package”. The components in modern day electronics generally appear to be rectangular black plastic packages with connector pins protruding from the plastic encasement. Often, many such packages are electrically coupled so that the chips therein form an electronic circuit to perform certain functions.

The software tools used for designing ICs produce, manipulate, or otherwise work with the circuit layout and circuit components on very small scales. Some of the components that such a tool may manipulate may only measure tens of nanometer across when formed in Silicon. The designs produced and manipulated using these software tools are complex, often including hundreds of thousands of such components interconnected to form an intended electronic circuitry.

A layout includes shapes that the designer selects and positions to achieve a design objective. The objective is to have the shape—the target shape—appear on the wafer as designed. However, the shapes may not appear exactly as designed when manufactured on the wafer through photolithography. For example, a rectangular shape with sharp corners may appear as a rectangular shape with rounded corners on the wafer.

Once a design layout, also referred to simply as a layout, has been finalized for an IC, the design is converted into a set of masks or reticles. A set of masks or reticles is one or more masks or reticles. During manufacture, a semiconductor wafer is exposed to light or radiation through a mask to form microscopic components of the IC. This process is known as photolithography.

A manufacturing mask is a mask usable for successfully manufacturing or printing the contents of the mask onto wafer. During the photolithographic printing process, radiation is focused through the mask and at certain desired intensity of the radiation. This intensity of the radiation is commonly referred to as “dose”. The focus and the dosing of the radiation has to be precisely controlled to achieve the desired shape and electrical characteristics on the wafer.

The software tools used for designing ICs produce, manipulate, or otherwise work with the circuit layout and circuit components on very small scales. Some of the components that such a tool may manipulate may only measure tens of nanometer across when formed in Silicon. The designs produced and manipulated using these software tools are complex, often including hundreds of thousands of such components interconnected to form an intended electronic circuitry.

Many semiconductor devices are planar, i.e., where the semiconductor structures are fabricated on one plane. A non-planar device is a three-dimensional (3D) device where some of the structures are formed above or below a given plane of fabrication.

A Field Effect Transistor (FET) is a semiconductor device that has controls the electrical conductivity between a source of electric current (source) and a destination of the electrical current (drain). The FET uses a semiconductor structure called a “gate” to create an electric field, which controls the shape and consequently the electrical conductivity of a channel between the source and the drain. The channel is a charge carrier pathway constructed using a semiconductor material.

Nanosheet transistor devices are becoming increasingly pursed as a viable semiconductor device option, especially for transistors at smaller scales, e.g., at five nanometer (nm) and smaller scales. A nanosheet FET transistor typically includes a substrate, an isolation layer, a number of vertically stacked nanosheets forming a channel, and a gate. A nanosheet is formed of a thin layer of semiconductor channel material having a vertical thickness that is less than a width of the material.

### SUMMARY

The illustrative embodiments provide a method and apparatus. An embodiment of a method for fabricating a nanosheet transistor includes receiving a substrate structure including a nanosheet stack having a plurality of nanosheet layers and a plurality of sacrificial layers stacked upon a substrate. In the embodiment, the substrate structure further includes a first fin and a second fin formed in the nanosheet stack. The embodiment further includes forming at least one dummy gate on the nanosheet stack. In the embodiment, the at least one dummy gate is formed of an amorphous material. The embodiment further includes recessing portions of the plurality of sacrificial layers, the plurality of nanosheet layers, and the substrate to form a fin recess between the first fin and the second fin.

The embodiment further includes performing an oxidation process to deposit an oxide layer on sidewalls of the first fin and the second fin to result in a faster oxidation of sidewalls of the sacrificial layers and the at least one dummy gate than oxidation of sidewalls the nanosheet layers. The embodiment further includes etching the oxide layer to substantially remove the oxide layer from the sidewalls of the nanosheet layers to form at least one inner spacer on at least one sidewall of the sacrificial layers and the dummy gate. The embodiment further includes selectively depositing a spacer dielectric material on the at least one dummy gate to form at least one outer spacer on the at least one inner spacer.

In an embodiment, the plurality of nanosheet layers are formed of a silicon (Si) material. In an embodiment, the plurality of sacrificial layers are formed of a silicon-germanium (SiGe) material.

An embodiment further includes forming a shallow trench isolation (STI) layer within the substrate adjacent to the first fin and the second fin.

In an embodiment, the amorphous material includes amorphous silicon-germanium (a-SiGe) material.

An embodiment further includes depositing a dummy gate oxide on the nanosheet stack, the dummy gate oxide disposed between the at least one gate and the nanosheet stack.

In an embodiment, a thicker layer of the oxide layer is deposited on the sidewalls of the at least one dummy gate and the sacrificial layers than a thickness of the oxide layer deposited on sidewalls the nanosheet layers.

In an embodiment, the oxidation process includes a wet oxidation at a temperature of less than or equal to 625 degrees C.

In an embodiment, the selective dielectric deposition deposits the spacer dielectric material only on the sidewalls of the sacrificial layers but not on the sidewalls of the nanosheet layers. In an embodiment, the spacer dielectric material is formed of a silicon nitride (SiN) material.

In an embodiment, etching the oxide layer further includes leaving a portion of the oxide layer on the at least one dummy gate and the sacrificial layers.

An embodiment further includes forming a source/drain on the substrate within the fin recess between the first fin and the second fin.

An embodiment further includes removing the at least one dummy gate, removing the plurality of sacrificial layers, and forming at least one gate in voids created by removal of the at least one gate and the plurality of sacrificial layers.

An embodiment of an apparatus includes a nanosheet stack having a plurality of nanosheet layers and a plurality of gate material layers stacked upon a substrate. In the embodiment, the nanosheet stack further includes a first fin and a second fin, and at least one gate formed on the nanosheet stack. The embodiment further includes at least one inner spacer disposed on at least one sidewall of the gate material layers and the at least one gate. In the embodiment, the at least one inner spacer is formed of an oxide layer in which a thicker layer of the oxide layer is deposited on the sidewalls of the at least one gate and the gate material layers than a thickness of the oxide layer deposited on sidewalls the nanosheet layers. The embodiment further includes at least one outer spacer formed on the at least one inner spacer. In the embodiment, the at least one outer spacer is formed of a spacer dielectric material.

In an embodiment, the spacer dielectric material is deposited only on the sidewalls of the gate material layers but not on the sidewalls of the nanosheet layers.

In an embodiment, the spacer dielectric material is formed of a silicon nitride (SiN) material.

An embodiment further includes a source/drain formed on the substrate between the first fin and the second fin.

An embodiment includes a computer usable program product. The computer usable program product includes one or more computer-readable storage devices, and program instructions stored on at least one of the one or more storage devices.

In an embodiment, the computer usable code is stored in a computer readable storage device in a data processing system, and wherein the computer usable code is transferred over a network from a remote data processing system.

In an embodiment, the computer usable code is stored in a computer readable storage device in a server data processing system, and wherein the computer usable code is downloaded over a network to a remote data processing system for use in a computer readable storage device associated with the remote data processing system.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of the illustrative embodiments when read in conjunction with the accompanying drawings, wherein:

FIG. 1 depicts a block diagram of a network of data processing systems in which illustrative embodiments may be implemented;

FIG. 2 depicts a block diagram of a data processing system in which illustrative embodiments may be implemented;

FIG. 3 depicts a cross-section view of a portion of a process for fabricating nanosheet transistors according to an illustrative embodiment;

FIG. 4 depicts cross-section views of another portion of the process according to an illustrative embodiment;

FIG. 5 depicts cross-section views of another portion of the process according to an illustrative embodiment;

FIG. 6 depicts cross-section views of another portion of the process according to an illustrative embodiment;

FIG. 7 depicts cross-section views of another portion of the process according to an illustrative embodiment;

FIG. 8 depicts cross-section views of another portion of the process according to an illustrative embodiment;

FIG. 9 depicts cross-section views of another portion of the process according to an illustrative embodiment;

FIG. 10 depicts cross-section views of another portion of the process according to an illustrative embodiment;

FIG. 11 depicts cross-section views of another portion of the process according to an illustrative embodiment; and

FIG. 12 depicts a flowchart of an example process for fabricating nanosheet transistors in accordance with an illustrative embodiment.

### DETAILED DESCRIPTION

The illustrative embodiments relate to a method for fabricating nanosheet transistors with inner spacers at highly scaled gate pitch and a structure formed by the method. The illustrative embodiments recognize that nanosheet transistor fabrication is a leading device architecture for continuing CMOS scaling. The illustrative embodiments recognize that fabrication of the inner spacer is one of most critical and challenging elements in nanosheet transistors manufacture. The illustrative embodiments recognize that a conventional process to form an inner spacer is by a three step process: (1) indenting sacrificial silicon-germanium (SiGe) to create a divot; (2) conformal depositing of a dielectric to pinch off the divot; and (3) dielectric etch back to remove extra dielectric at the nanosheet ends while leaving dielectric in the divot. Such a process is often referred to as ‘divot fill’ approach.

The illustrative embodiments recognize that while the ‘divot fill’ approach works to make a nanosheet transistor with large contact gate pitch (CPP), such an approach suffers from several problems, in particular when scaling nanosheets below very aggressive CPP, for example, 44 nm. For example, illustrative embodiments recognize that the conformal dielectric deposition after indenting may pinch off the small gap between adjacent gates as a smaller CPP results in a smaller gap between adjacent gates. Once pinch-off occurs, it becomes extremely challenging, if not impossible, to reliably form inner spacer.

In another example, illustrative embodiments recognize that the aspect ratio of the indent (i.e., lateral indenting width divided by the vertical thickness of the sacrificial SiGe thickness) becomes smaller due partly to reducing of inner spacer thickness for highly scaled nanosheet transistor and due partly to the minimal inner spacer thickness requirement to accommodate a high-k/work function metal. For example, for a spacer thickness of 5 nm, and an inner spacer thickness of 10 nm, the indent has an aspect ratio of 1:2. The illustrative embodiments recognize that the conventional divot fill approach may not work well for such a ‘shallow’ divot. The illustrative embodiments recognize that there is a need for forming inner spacers in nanosheet transistors suitable for highly scaled CPP.

In one or more embodiments, a process of forming a nanosheet-FET gate spacer and inner spacers includes selective growth of silicon nitride (SiN) or low-k on selectively oxidized SiGe to enable sub-44 nm CPP devices. One or more embodiments use (i) an amorphous SiGe dummy gate, (ii) a preferential SiGe oxidation and (iii) a selective dielectric deposition on a dielectric. One or more embodiments provide for reactive-ion etching-free inner spacer formation which (i) avoids liner pinch-off problems and (ii) works even with a large sacrificial SiGe suspension thickness and thin spacers independent of sacrificial SiGe suspension thickness.

An embodiment of a process for fabricating nanosheet transistors with inner spacers includes forming a nanosheet stack of alternating layers of nanosheet (e.g., Si) layers and sacrificial (SiGe) layers using epitaxial growth, forming fins on the nanosheet stack, and forming a shallow trench isolation (STI) on the nanosheet stack. The embodiment further includes forming a dummy gate of amorphous SiGe (a-SiGe), and recessing the fins to form source/drain regions without requiring a step of gate spacer deposition. The embodiment further includes performing a low temperature oxidation that oxidizes SiGe faster than silicon (Si) resulting in much thicker oxide on SiGe sidewalls than that on Si sidewalls. In a particular embodiment, a wet oxidation at 625 degrees C. can oxidize SiGe25% at least ten times faster than Si.

The embodiment further includes performing an isotropic silicon oxide (SiO) etch back to remove thin SiO from Si sidewalls while still leaving some SiO on SiGe sidewalls. The embodiment further includes selective dielectric deposition that deposits spacer dielectric material only on dielectric surfaces of the sidewalls but not on Si surfaces of the sidewall. The embodiment further includes forming the source/drains using a dual (TJ/RG) epitaxy, depositing an interlayer dielectric (ILD), and removing a dummy gate oxide. The embodiment further includes removing the dummy gate, removing the sacrificial (SiGe) layers, forming a high-K metal gate stack (HKMG), forming an insulative (e.g., SiN) cap, and forming contacts.

One or more embodiments may provide an advantage of enabling inner spacer formation of a nanosheet-FET at highly scaled CPP. One or more embodiments may provide another advantage of forming both the outer spacer and the inner spacers at the same time without requiring the user of a conventional spacer deposition/RIE processes which avoids the spacer pinch-off problem, works even with large sacrificial SiGe thickness and a thin spacer, and is independent of sacrificial SiGe thickness. One or more embodiments may provide an advantage of requiring fewer process steps than conventional approaches as both outer and inner spacers are formed at the same time.

An embodiment can be implemented as a software application. The application implementing an embodiment can be configured as a modification of an existing fabrication system, as a separate application that operates in conjunction with an existing fabrication system, a standalone application, or some combination thereof. For example, the application causes the fabrication system to perform the steps described herein, to fabricate nanosheet transistors.

For the clarity of the description, and without implying any limitation thereto, the illustrative embodiments are described using FET a nanosheet transistor disposed on a substrate. An embodiment can be implemented with different types and/or numbers of nanosheet transistors, a number of gates, and/or a different number of substrates within the scope of the illustrative embodiments.

Furthermore, a simplified diagram of the example nanosheet FETs are used in the figures and the illustrative embodiments. In an actual fabrication of a nanosheet transistors, additional structures that are not shown or described herein may be present without departing the scope of the illustrative embodiments. Similarly, within the scope of the illustrative embodiments, a shown or described structure in the example nanosheet transistors may be fabricated differently to yield a similar operation or result as described herein.

Differently shaded portions in the two-dimensional drawing of the example nanosheet transistors are intended to represent different structures in the example nanosheet transistors, as described herein. The different structures may be fabricated using suitable materials that are known to those of ordinary skill in the art.

A specific shape or dimension of a shape depicted herein is not intended to be limiting on the illustrative embodiments. The shapes and dimensions are chosen only for the clarity of the drawings and the description and may have been exaggerated, minimized, or otherwise changed from actual shapes and dimensions that might be used in actually fabricating nanosheet transistors according to the illustrative embodiments.

Furthermore, the illustrative embodiments are described with respect to nanosheet transistors only as an example. The steps described by the various illustrative embodiments can be adapted for fabricating other planar and non-planar devices employing nanosheets in a similar manner, and such adaptations are contemplated within the scope of the illustrative embodiments.

An embodiment when implemented in an application causes a fabrication process to perform certain steps as described herein. The steps of the fabrication process are depicted in the several figures. Not all steps may be necessary in a particular fabrication process. Some fabrication processes may implement the steps in different order, combine certain steps, remove or replace certain steps, or perform some combination of these and other manipulations of steps, without departing the scope of the illustrative embodiments.

A method of an embodiment described herein, when implemented to execute on a device or data processing system, comprises substantial advancement of the functionality of that device or data processing system in fabricating nanosheet transistor devices. An embodiment provides a method for fabricating nanosheet transistors.

The illustrative embodiments are described with respect to certain types of devices, contacts, layers, planes, structures, materials, dimensions, numerosity, data processing systems, environments, components, and applications only as examples. Any specific manifestations of these and other similar artifacts are not intended to be limiting to the invention. Any suitable manifestation of these and other similar artifacts can be selected within the scope of the illustrative embodiments.

Furthermore, the illustrative embodiments may be implemented with respect to any type of data, data source, or access to a data source over a data network. Any type of data storage device may provide the data to an embodiment of the invention, either locally at a data processing system or over a data network, within the scope of the invention. Where an embodiment is described using a mobile device, any type of data storage device suitable for use with the mobile device may provide the data to such embodiment, either locally at the mobile device or over a data network, within the scope of the illustrative embodiments.

The illustrative embodiments are described using specific code, designs, architectures, protocols, layouts, schematics, and tools only as examples and are not limiting to the illustrative embodiments. Furthermore, the illustrative embodiments are described in some instances using particular software, tools, and data processing environments only as an example for the clarity of the description. The illustrative embodiments may be used in conjunction with other comparable or similarly purposed structures, systems, applications, or architectures. For example, other comparable mobile devices, structures, systems, applications, or architectures therefor, may be used in conjunction with such embodiment of the invention within the scope of the invention. An illustrative embodiment may be implemented in hardware, software, or a combination thereof.

The examples in this disclosure are used only for the clarity of the description and are not limiting to the illustrative embodiments. Additional data, operations, actions, tasks, activities, and manipulations will be conceivable from this disclosure and the same are contemplated within the scope of the illustrative embodiments.

Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

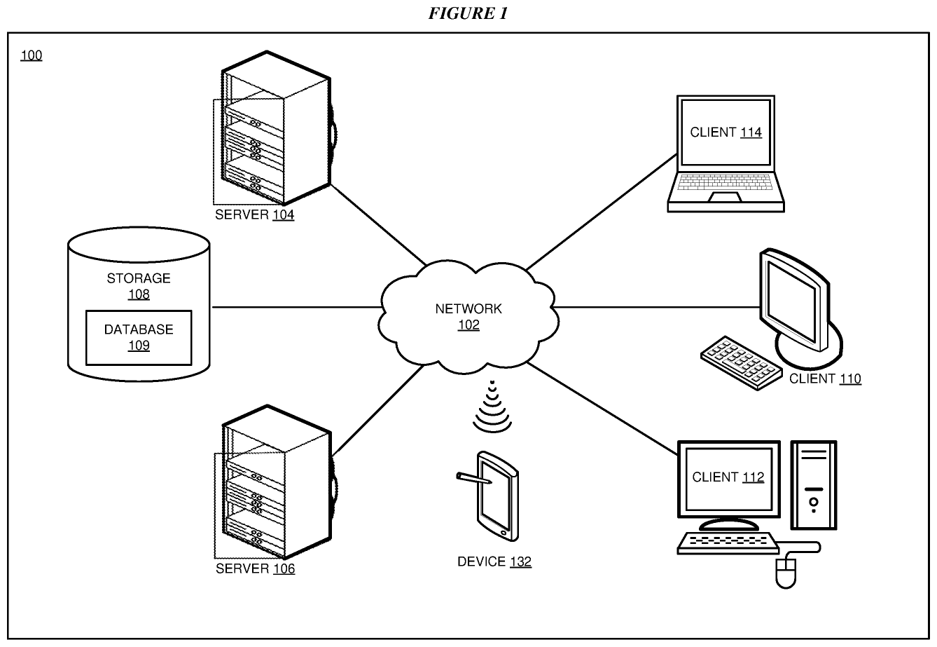

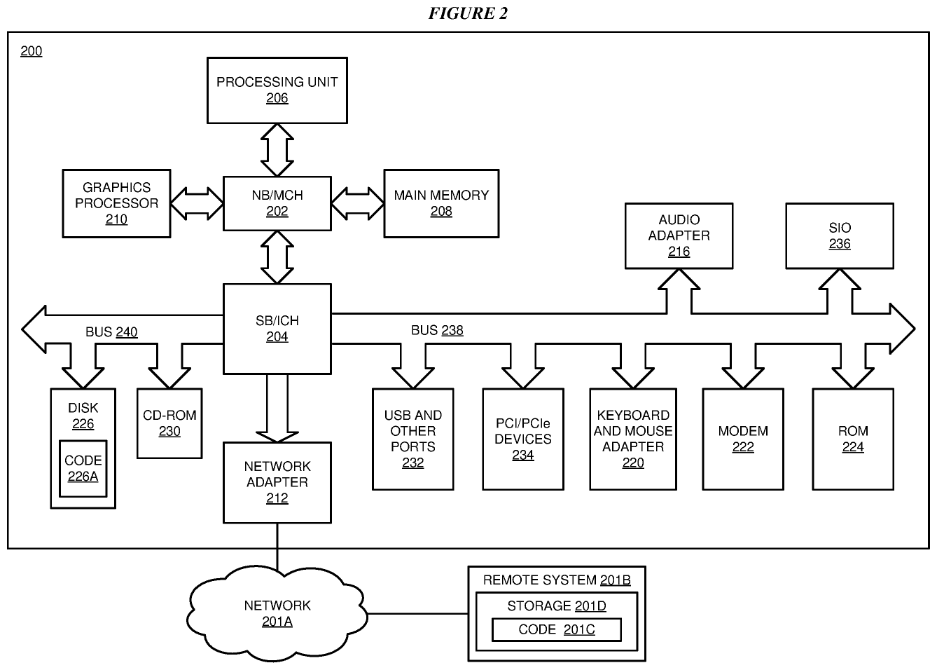

With reference to the figures and in particular with reference to FIGS. 1 and 2, these figures are example diagrams of data processing environments in which illustrative embodiments may be implemented. FIGS. 1 and 2 are only examples and are not intended to assert or imply any limitation with regard to the environments in which different embodiments may be implemented. A particular implementation may make many modifications to the depicted environments based on the following description.

FIG. 1 depicts a block diagram of a network of data processing systems in which illustrative embodiments may be implemented. Data processing environment 100 is a network of computers in which the illustrative embodiments may be implemented. Data processing environment 100 includes network 102. Network 102 is the medium used to provide communications links between various devices and computers connected together within data processing environment 100. Network 102 may include connections, such as wire, wireless communication links, or fiber optic cables.

Clients or servers are only example roles of certain data processing systems connected to network 102 and are not intended to exclude other configurations or roles for these data processing systems. Server 104 and server 106 couple to network 102 along with storage unit 108. Software applications may execute on any computer in data processing environment 100. Clients 110, 112, and 114 are also coupled to network 102. A data processing system, such as server 104 or 106, or client 110, 112, or 114 may contain data and may have software applications or software tools executing thereon.

Only as an example, and without implying any limitation to such architecture, FIG. 1 depicts certain components that are usable in an example implementation of an embodiment. For example, servers 104 and 106, and clients 110, 112, 114, are depicted as servers and clients only as example and not to imply a limitation to a client-server architecture. As another example, an embodiment can be distributed across several data processing systems and a data network as shown, whereas another embodiment can be implemented on a single data processing system within the scope of the illustrative embodiments. Data processing systems 104, 106, 110, 112, and 114 also represent example nodes in a cluster, partitions, and other configurations suitable for implementing an embodiment.

Device 132 is an example of a device described herein. For example, device 132 can take the form of a smartphone, a tablet computer, a laptop computer, client 110 in a stationary or a portable form, a wearable computing device, or any other suitable device. Any software application described as executing in another data processing system in FIG. 1 can be configured to execute in device 132 in a similar manner. Any data or information stored or produced in another data processing system in FIG. 1 can be configured to be stored or produced in device 132 in a similar manner.

Application 105 implements an embodiment described herein. Fabrication system 107 is any suitable system for fabricating a semiconductor device. Application 105 provides instructions to system 107 for fabricating one or more nanosheet transistors in a manner described herein.

Servers 104 and 106, storage unit 108, and clients 110, 112, and 114 may couple to network 102 using wired connections, wireless communication protocols, or other suitable data connectivity. Clients 110, 112, and 114 may be, for example, personal computers or network computers.

In the depicted example, server 104 may provide data, such as boot files, operating system images, and applications to clients 110, 112, and 114. Clients 110, 112, and 114 may be clients to server 104 in this example. Clients 110, 112, 114, or some combination thereof, may include their own data, boot files, operating system images, and applications. Data processing environment 100 may include additional servers, clients, and other devices that are not shown.

In the depicted example, data processing environment 100 may be the Internet. Network 102 may represent a collection of networks and gateways that use the Transmission Control Protocol/Internet Protocol (TCP/IP) and other protocols to communicate with one another. At the heart of the Internet is a backbone of data communication links between major nodes or host computers, including thousands of commercial, governmental, educational, and other computer systems that route data and messages. Of course, data processing environment 100 also may be implemented as a number of different types of networks, such as for example, an intranet, a local area network (LAN), or a wide area network (WAN). FIG. 1 is intended as an example, and not as an architectural limitation for the different illustrative embodiments.

Among other uses, data processing environment 100 may be used for implementing a client-server environment in which the illustrative embodiments may be implemented. A client-server environment enables software applications and data to be distributed across a network such that an application functions by using the interactivity between a client data processing system and a server data processing system. Data processing environment 100 may also employ a service oriented architecture where interoperable software components distributed across a network may be packaged together as coherent business applications.

With reference to FIG. 2, this figure depicts a block diagram of a data processing system in which illustrative embodiments may be implemented. Data processing system 200 is an example of a computer, such as servers 104 and 106, or clients 110, 112, and 114 in FIG. 1, or another type of device in which computer usable program code or instructions implementing the processes may be located for the illustrative embodiments.

Data processing system 200 is also representative of a data processing system or a configuration therein, such as data processing system 132 in FIG. 1 in which computer usable program code or instructions implementing the processes of the illustrative embodiments may be located. Data processing system 200 is described as a computer only as an example, without being limited thereto. Implementations in the form of other devices, such as device 132 in FIG. 1, may modify data processing system 200, such as by adding a touch interface, and even eliminate certain depicted components from data processing system 200 without departing from the general description of the operations and functions of data processing system 200 described herein.

In the depicted example, data processing system 200 employs a hub architecture including North Bridge and memory controller hub (NB/MCH) 202 and South Bridge and input/output (I/O) controller hub (SB/ICH) 204. Processing unit 206, main memory 208, and graphics processor 210 are coupled to North Bridge and memory controller hub (NB/MCH) 202. Processing unit 206 may contain one or more processors and may be implemented using one or more heterogeneous processor systems. Processing unit 206 may be a multi-core processor. Graphics processor 210 may be coupled to NB/MCH 202 through an accelerated graphics port (AGP) in certain implementations.

In the depicted example, local area network (LAN) adapter 212 is coupled to South Bridge and I/O controller hub (SB/ICH) 204. Audio adapter 216, keyboard and mouse adapter 220, modem 222, read only memory (ROM) 224, universal serial bus (USB) and other ports 232, and PCI/PCIe devices 234 are coupled to South Bridge and I/O controller hub 204 through bus 238. Hard disk drive (HDD) or solid-state drive (SSD) 226 and CD-ROM 230 are coupled to South Bridge and I/O controller hub 204 through bus 240. PCI/PCIe devices 234 may include, for example, Ethernet adapters, add-in cards, and PC cards for notebook computers. PCI uses a card bus controller, while PCIe does not. ROM 224 may be, for example, a flash binary input/output system (BIOS). Hard disk drive 226 and CD-ROM 230 may use, for example, an integrated drive electronics (IDE), serial advanced technology attachment (SATA) interface, or variants such as external-SATA (eSATA) and micro-SATA (mSATA). A super I/O (SIO) device 236 may be coupled to South Bridge and I/O controller hub (SB/ICH) 204 through bus 238.

Memories, such as main memory 208, ROM 224, or flash memory (not shown), are some examples of computer usable storage devices. Hard disk drive or solid state drive 226, CD-ROM 230, and other similarly usable devices are some examples of computer usable storage devices including a computer usable storage medium.

An operating system runs on processing unit 206. The operating system coordinates and provides control of various components within data processing system 200 in FIG. 2. The operating system may be a commercially available operating system such as AIX® (AIX is a trademark of International Business Machines Corporation in the United States and other countries), Microsoft® Windows® (Microsoft and Windows are trademarks of Microsoft Corporation in the United States and other countries), Linux® (Linux is a trademark of Linus Torvalds in the United States and other countries), iOS™ (iOS is a trademark of Cisco Systems, Inc. licensed to Apple Inc. in the United States and in other countries), or Android™ (Android is a trademark of Google Inc., in the United States and in other countries). An object oriented programming system, such as the Java™ programming system, may run in conjunction with the operating system and provide calls to the operating system from Java™ programs or applications executing on data processing system 200 (Java and all Java-based trademarks and logos are trademarks or registered trademarks of Oracle Corporation and/or its affiliates).

Instructions for the operating system, the object-oriented programming system, and applications or programs, such as application 105 in FIG. 1, are located on storage devices, such as in the form of code 226A on hard disk drive 226, and may be loaded into at least one of one or more memories, such as main memory 208, for execution by processing unit 206. The processes of the illustrative embodiments may be performed by processing unit 206 using computer implemented instructions, which may be located in a memory, such as, for example, main memory 208, read only memory 224, or in one or more peripheral devices.

Furthermore, in one case, code 226A may be downloaded over network 201A from remote system 201B, where similar code 201C is stored on a storage device 201D. in another case, code 226A may be downloaded over network 201A to remote system 201B, where downloaded code 201C is stored on a storage device 201D.

The hardware in FIGS. 1-2 may vary depending on the implementation. Other internal hardware or peripheral devices, such as flash memory, equivalent non-volatile memory, or optical disk drives and the like, may be used in addition to or in place of the hardware depicted in FIGS. 1-2. In addition, the processes of the illustrative embodiments may be applied to a multiprocessor data processing system.

In some illustrative examples, data processing system 200 may be a personal digital assistant (PDA), which is generally configured with flash memory to provide non-volatile memory for storing operating system files and/or user-generated data. A bus system may comprise one or more buses, such as a system bus, an I/O bus, and a PCI bus. Of course, the bus system may be implemented using any type of communications fabric or architecture that provides for a transfer of data between different components or devices attached to the fabric or architecture.

A communications unit may include one or more devices used to transmit and receive data, such as a modem or a network adapter. A memory may be, for example, main memory 208 or a cache, such as the cache found in North Bridge and memory controller hub 202. A processing unit may include one or more processors or CPUs.

The depicted examples in FIGS. 1-2 and above-described examples are not meant to imply architectural limitations. For example, data processing system 200 also may be a tablet computer, laptop computer, or telephone device in addition to taking the form of a mobile or wearable device.

Where a computer or data processing system is described as a virtual machine, a virtual device, or a virtual component, the virtual machine, virtual device, or the virtual component operates in the manner of data processing system 200 using virtualized manifestation of some or all components depicted in data processing system 200. For example, in a virtual machine, virtual device, or virtual component, processing unit 206 is manifested as a virtualized instance of all or some number of hardware processing units 206 available in a host data processing system, main memory 208 is manifested as a virtualized instance of all or some portion of main memory 208 that may be available in the host data processing system, and disk 226 is manifested as a virtualized instance of all or some portion of disk 226 that may be available in the host data processing system. The host data processing system in such cases is represented by data processing system 200.

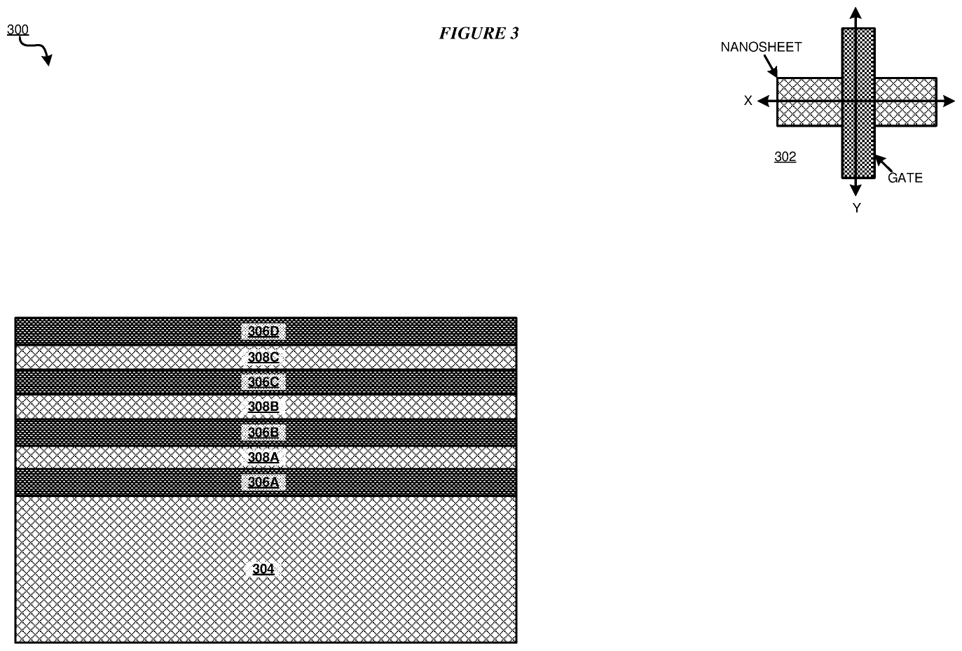

With reference to FIGS. 3-11, these figures depict portions of an example process for fabricating nanosheet transistors with inner spacers at highly scaled gate pitch in accordance with one or more illustrative embodiments. One or more of FIGS. 3-11 illustrate a first cross-section view along a first direction X perpendicular to a gate of the nanosheet transistor structure, and a second cross-section view along a second direction Y perpendicular to a fin of the nanosheet transistor structure. In the particular embodiments illustrated in FIGS. 3-11, two adjacent vertical transistors devices fabricated upon a substrate and/or wafer. It should be understood that in other embodiments, any combination of transistors or other combinations of any numbers of semiconductor devices, may be fabricated on a substrate in a similar manner.

With reference to FIG. 3, this figure depicts cross-section views of a portion of a process for fabricating nanosheet transistors in which an example structure 300 is formed according to an illustrative embodiment. FIG. 3 shows a top down view 302 showing the X and Y directions of the cross sections of one or more of and FIGS. 3-11. In the embodiment, fabrication system 107 receives structure 300 including a nanosheet stack having a substrate 304, a first sacrificial layer 306A formed on substrate 304, a first nanosheet layer 308A formed on first sacrificial layer 306A, a second sacrificial layer 306B formed on first nanosheet layer 308A, a second nanosheet layer 308B formed on second sacrificial layer 306B, a third sacrificial layer 306C formed on second nanosheet layer 308B, a third nanosheet layer 308C formed on third sacrificial layer 306C, and a fourth sacrificial layer 306D formed on third nanosheet layer 308C. In a particular embodiment, substrate 304 is formed of an Si material. In a particular embodiment, sacrificial layers 306A-306D are formed of a SiGe material. In a particular embodiment, the SiGe layers have a germanium concentration of 35%. In a particular embodiment, nanosheet layers 308A-308C are formed of an Si material. In a particular embodiment, nanosheet layers 308A-308C have a thickness of approximately 8 nm and sacrificial layers 306A-306D have a thickness of approximately 9 nm. It should be understood that in other embodiments, other germanium concentrations could be used. Although embodiments described herein are shown as using three nanosheet layers and four sacrificial layers in the nanosheet stack, it should be understood that in other embodiments any desired number of layers forming the nanosheet stack may be used.

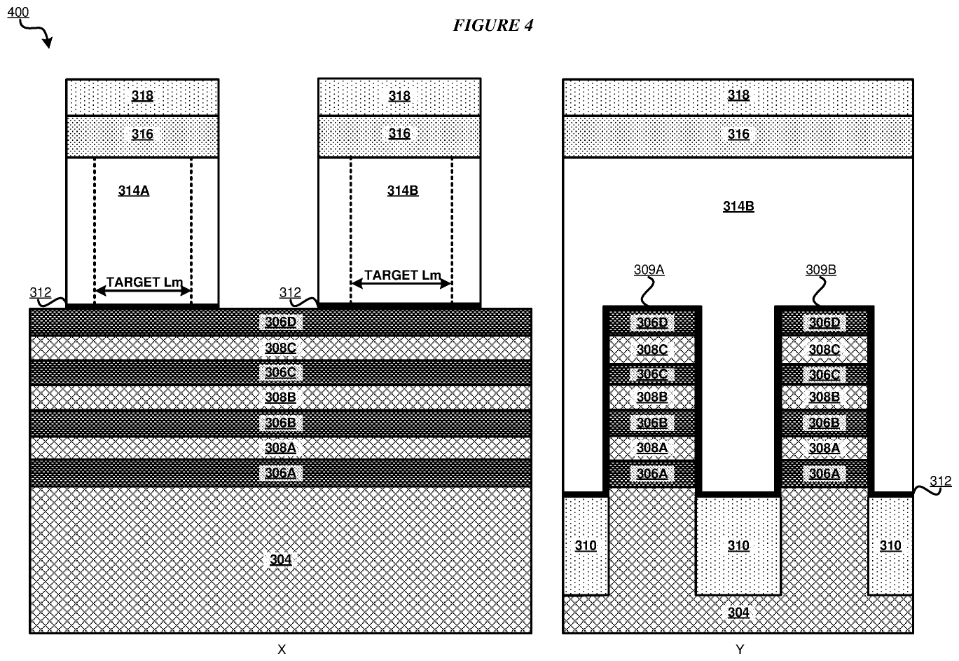

With reference to FIG. 4, FIG. 4 depicts cross-section views of another portion of the process in which a structure 400 is formed according to an illustrative embodiment. In the embodiment, fabrication system 107 forms a first fin 309A and a second fin 309B of the nanosheet stack by an etching process, and deposits a shallow trench isolation (STI) layer 310 within substrate 304 adjacent to first fin 309A and second fin 309B. In the embodiment, fabrication system 107 deposits a conformal dummy gate oxide 312 encapsulating first fin 309A and second fin 309B.

In the embodiment, fabrication system 107 deposits and patterns a first dummy gate 314A and a second dummy gate 314B on dummy gate oxide 312. In an embodiment, a dummy gate critical dimension of first dummy gate 314A and a second dummy gate 314B is greater than the targeted final gate length (Lmetal=Lm) of the final device. In one or more embodiments, fabrication system 107 deposits a dummy gate material and planarizes the dummy gate material to form first dummy gate 314A and a second dummy gate 314B. In at least one embodiment, first dummy gate 314A and second dummy gate 314B are formed with amorphous SiGe (a-SiGe). In one or more embodiments, amorphous SiGe refers to SiGe that does not have a crystalline structure. In particular embodiments, first dummy gate 314A and second dummy gate 314B are formed with a-SiGe instead of amorphous Si (a-Si) so that the outer spacer and the inner spacer can be formed at the same time by selective oxidation and selective deposition.

In the embodiment, fabrication system 107 deposits a layer 316 upon first dummy gate 314A and second dummy gate 314B. In a particular embodiment, layer 316 is a conformal deposition layer. In a particular embodiment, layer 316 is a SiN layer. In the embodiment, fabrication system 107 deposits a gate liner layer 318 upon layer 316. In a particular embodiment, gate liner layer 318 is a silicon oxide (SiO) layer. In particular embodiments, layer 316 and gate liner layer 318 constitute a gate hardmask. In other particular embodiments, other suitable combinations of multiple layers can be used to form a gate hardmask. In one or more embodiments, fabrication system 107 further performs gate patterning by directional RIE to transfer patterns by cutting gate liner layer 318, layer 316, first dummy gate 314A, and second dummy gate 314B to stop at conformal dummy gate oxide 312. In an embodiment, fabrication system 107 further uses a wet removal process to remove conformal dummy gate oxide 312 such that conformal dummy gate oxide 312 is self-aligned to the patterned dummy gate stack of first dummy gate 314A and second dummy gate 314B.

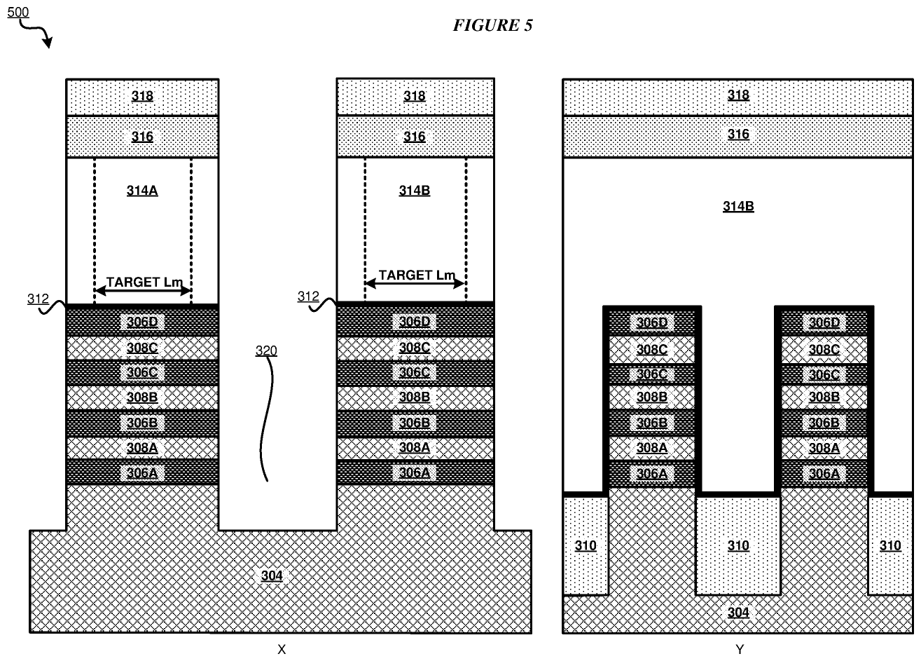

With reference to FIG. 5, FIG. 5 depicts cross-section views of another portion of the process in which a structure 500 is formed according to an illustrative embodiment. In the embodiment, fabrication system 107 recesses portions of sacrificial layers 306A-306D, nanosheet layers 308A-308C, and substrate 304 to form a fin recess 320 between first fin 309A and second fin 309B to form a source/drain region. In a particular embodiment, fabrication system 107 forms fin recess 320 using an etching process such as by a reactive-ion etching (RIE) process.

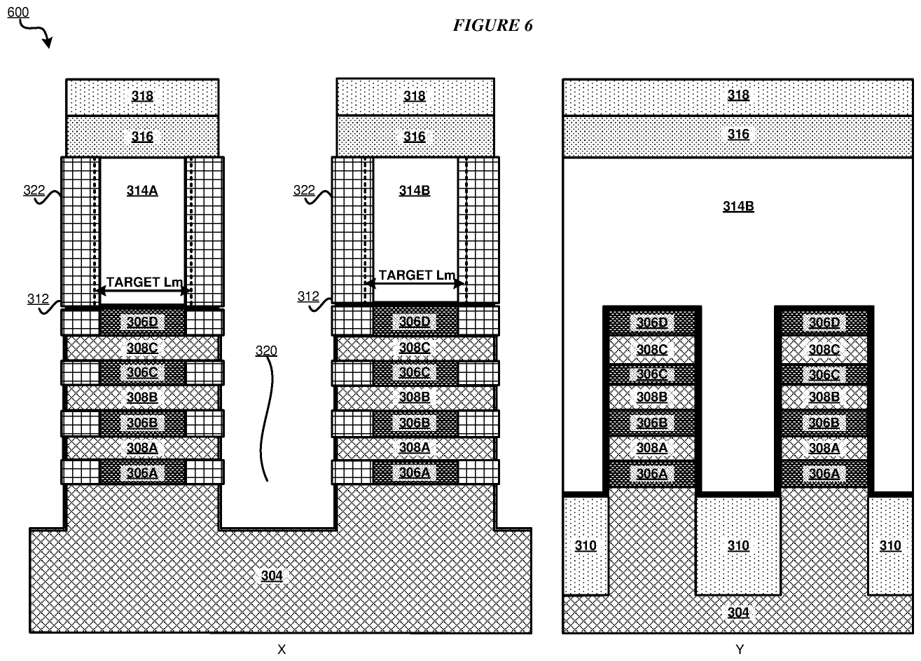

With reference to FIG. 6, FIG. 6 depicts cross-section views of another portion of the process in which a structure 600 is formed according to an embodiment. In the embodiment, fabrication system 107 performs a low temperature oxidation process that oxidizes SiGe faster than Si resulting in much thicker oxide on SiGe sidewalls than that on Si sidewalls to form an oxide layer 322 on sidewalls of first fin 309A and second fin 309B. As a result, a thicker layer of oxide layer 322 is deposited on sidewalls of first dummy gate 314A, second dummy gate 314B, and sacrificial layers 306A-306D, than the thickness oxide layer 322 deposited on sidewalls of nanosheet layers 308A-308C. In a particular embodiment, a wet oxidation at a temperature of 625 degrees C. or lower is used.

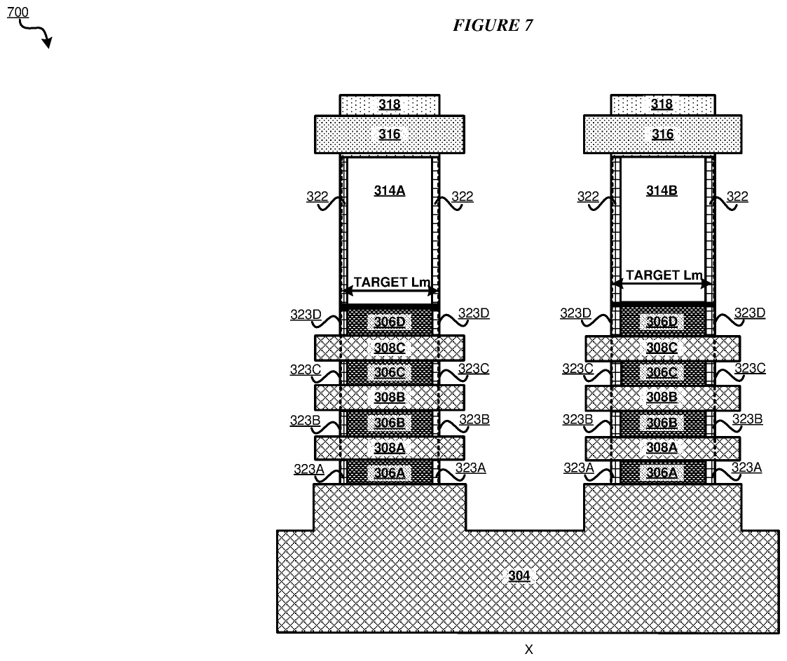

With reference to FIG. 7, FIG. 7 depicts cross-section views of another portion of the process in which a structure 700 is formed according to an embodiment. In the embodiment, fabrication system 107 etches back oxide layer 322 to remove oxide layer 322 from sidewalls of nanosheet layers 308A-308C while leaving a portion of oxide layer 322 on first dummy gate 314A, second dummy gate 314B, and sacrificial layers 306A-306D. As a result, first sacrificial inner spacers 323A are formed on sidewalls of first sacrificial layer 306A, second sacrificial inner spacers 323B are formed on sidewalls of second sacrificial layer 306B, third sacrificial inner spacers 323C are formed on sidewalls of third sacrificial layer 306C, and fourth sacrificial inner spacers 323D are formed on sidewalls of fourth sacrificial layer 306D, first dummy gate 314A and second dummy gate 314B. In one or more embodiments, sacrificial inner spacers 323A-323D are used as a seed layer for the growth of a final SiN inner spacer. In a particular embodiment, fabrication system 107 performs an isotropic silicon oxide (SiO) etch back to remove oxide layer 322.

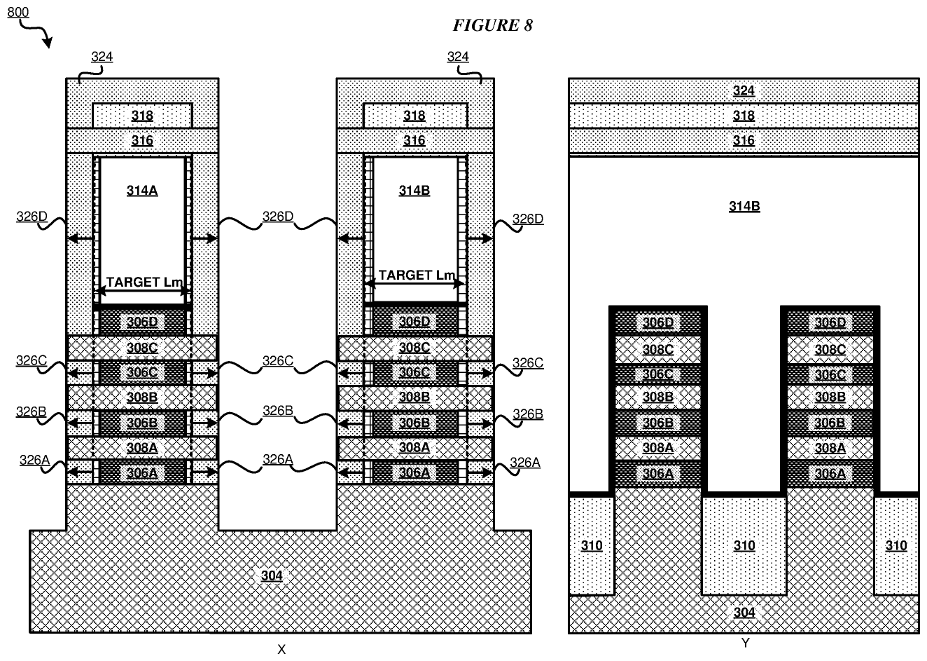

With reference to FIG. 8, FIG. 8 depicts cross-section views of another portion of the process in which a structure 800 is formed according to an embodiment. In the embodiment, fabrication system 107 selectively deposits a spacer dielectric material 324 to form first outer spacers 326A on first sacrificial inner spacers 323A, second outer spacers 326B on second sacrificial inner spacers 323B, third outer spacers 326A on third sacrificial inner spacers 323A, and fourth outer spacers 326D on fourth sacrificial inner spacers 323D. In a particular embodiment, the selective dielectric deposition deposits the spacer dielectric material only on dielectric surfaces of the sidewalls of the SiGe surfaces but not on Si surfaces of the sidewalls. It should be noted that the oxide and nitride surfaces are hydrophilic. In contrast, the Si surfaces are hydrophobic. Accordingly, selective dielectric deposition on dielectric (DoD) can be performed to deposit the spacer dielectric material only on dielectric surfaces of the sidewalls, not silicon surfaces of the sidewalls. In a particular embodiment, spacer dielectric material 324 is formed of SiN material.

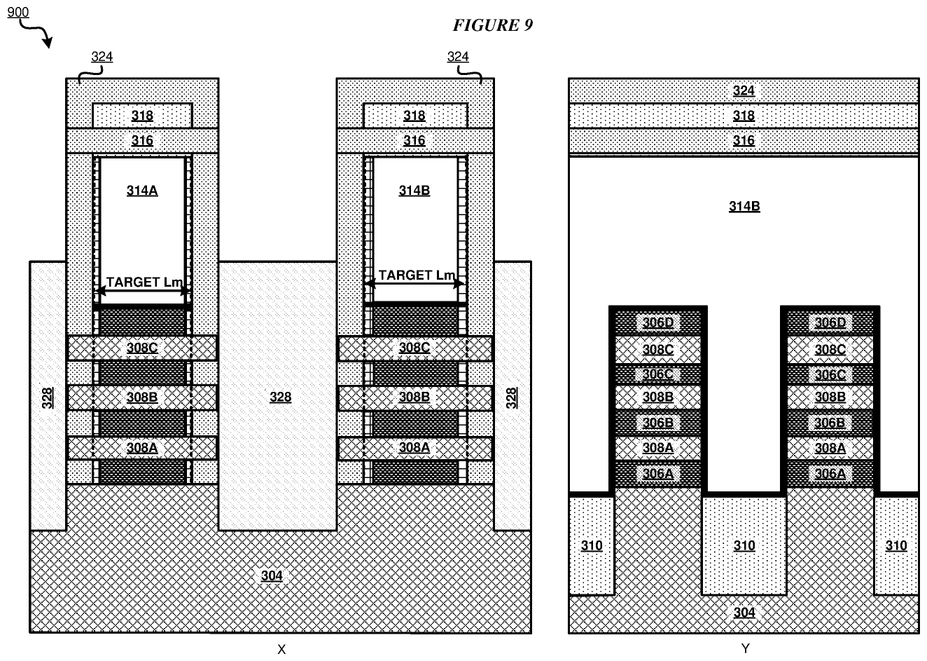

With reference to FIG. 9, FIG. 9 depicts cross-section views of another portion of the process in which a structure 900 is formed according to an embodiment. In the embodiment, fabrication system 107 forms a source/drain 328 on substrate 304 within fin recess 320 between first fin 309A and second fin 309B. In a particular embodiment, fabrication system 107 forms source/drain 328 using a dual pFET/nFET epitaxy process sequence.

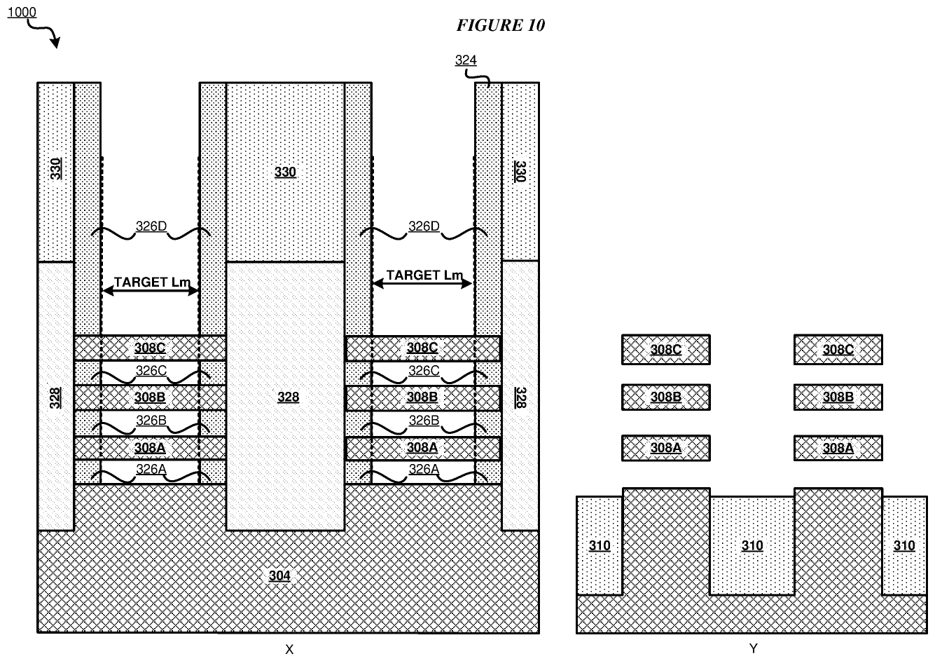

With reference to FIG. 10, FIG. 10 depicts cross-section views of another portion of the process in which a structure 1000 is formed according to an embodiment. In the embodiment, fabrication system 107 deposits an interlayer dielectric (ILD) 330 upon source/drain 328. In a particular embodiment, ILD 330 is formed of a silicon dioxide (SiO2) material. In the embodiment, fabrication system 107 removes first dummy gate 314A, and second dummy gate 314B, and further removes dummy gate oxide 312. In the embodiment, fabrication system 107 further removes sacrificial layers 306A-306D.

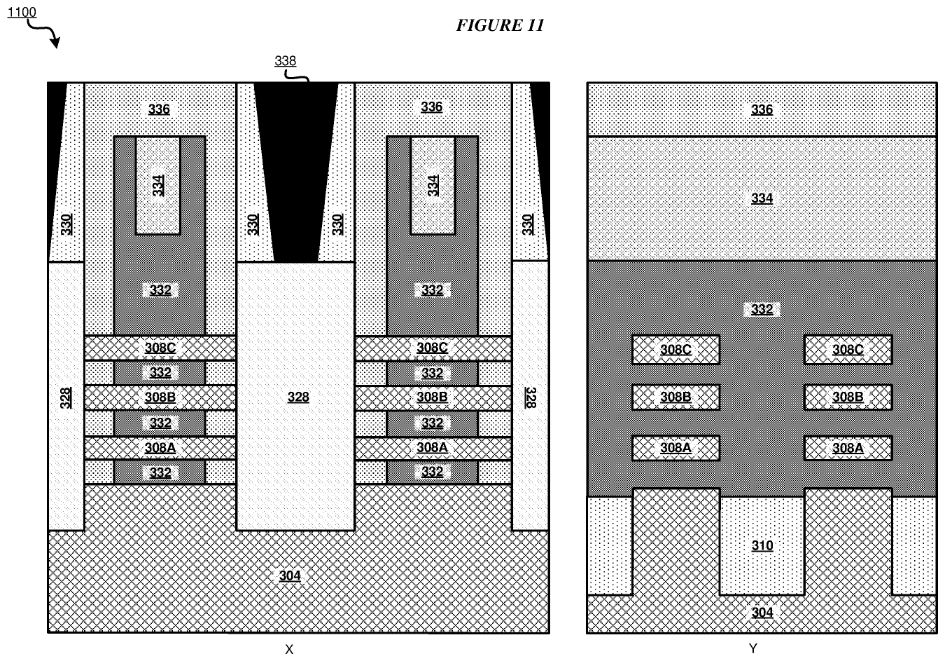

With reference to FIG. 11, FIG. 11 depicts cross-section views of another portion of the process in which a structure 1100 is formed according to an embodiment. In the embodiment, fabrication system 107 forms a high-K metal gate (HKMG) stack 332 in the voids created by the removal of first dummy gate 314A, second dummy gate 314B, and sacrificial layers 306A-306D, and a metal gate fill layer 334 in HKMG stack 332. In a particular embodiment, HKMG stack 332 is composed of an interface layer dielectric material, a gate dielectric material, a gate dielectric material, and a metal electrode. The interface layer of the gate stack may be composed of a dielectric material, such as an oxide of silicon (e.g., silicon dioxide (SiO2)). The gate dielectric layer of the gate stack may be composed of a dielectric material, such as a high-k dielectric material like hafnium oxide (HfO2). The metal gate electrode of the gate stack includes one or more conformal barrier metal layers and/or work function metal layers, such as layers composed of titanium aluminum carbide (TiAlC) and/or titanium nitride (TiN), and a metal gate fill layer composed of a conductor, such as tungsten (W). The metal gate electrode of the gate stack may include different combinations of the conformal barrier metal layers and/or work function metal layers. For example, the metal gate electrode may include conformal work function metal layers characteristic of a p-type field-effect transistor. As another example, the metal gate electrode may include conformal work function metal layers characteristic of an n-type field-effect transistor.

In the embodiment, fabrication system 107 forms an insulative cap 336 upon the gates formed by HKMG stack 332 and metal gate fill layer 334. In a particular embodiment, insulative cap 336 is formed of a SiN material. In the embodiment, fabrication system 107 forms a source/drain (S/D) contact (TS) 338 in contact with S/D 328. As a result, an nanosheet transistor is fabricated according to an illustrative embodiment.

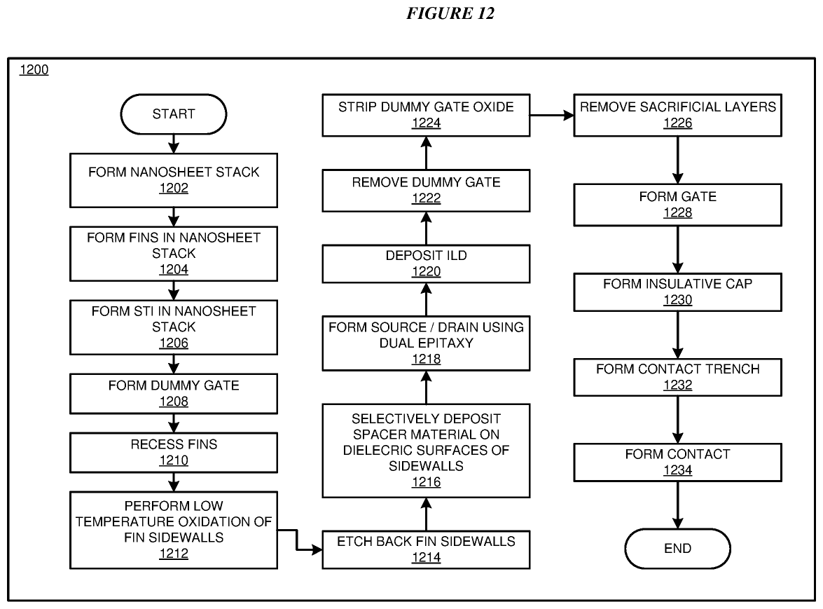

With reference to FIG. 12, FIG. 12 depicts a flowchart of an example process 1200 for fabricating nanosheet transistors in accordance with one or more illustrative embodiments. Process 1200 can be implemented in fabrication system 107 in FIG. 1, to perform one or more steps of FIGS. 3-11 as needed in process 1200.

In block 1202, fabrication system 107 forms a nanosheet stack including substrate 304, first sacrificial layer 306A formed on substrate 304, first nanosheet layer 308A formed on first sacrificial layer 306A, second sacrificial layer 306B formed on first nanosheet layer 308A, second nanosheet layer 308B formed on second sacrificial layer 306B, third sacrificial layer 306C formed on second nanosheet layer 308B, third nanosheet layer 308C formed on third sacrificial layer 306C, and fourth sacrificial layer 306D formed on third nanosheet layer 308C. In a particular embodiment, substrate 304 is formed of an Si material. In a particular embodiment, sacrificial layers 306A-306D are formed of a SiGe material. In a particular embodiment, nanosheet layers 308A-308C are formed of an Si material.

In block 1204, fabrication system 107 forms first fin 309A and second fin 309B in the nanosheet stack. In a particular embodiment, fabrication system 107 forms first fin 309A and second fin 309B by an etching process. In block 1206, fabrication system 107 forms STI layer 310 within substrate 304 adjacent to first fin 309A and second fin 309B. In block 1208, fabrication system 107 deposits a dummy gate oxide 312 and forms first dummy gate 314A and second dummy gate 314B on dummy gate oxide 312. In a particular embodiment, fabrication system 107 forms first dummy gate 314A and second dummy gate 314B by depositing and patterning first dummy gate 314A and second dummy gate 314B on dummy gate oxide 312 of the nanosheet stack. In one or more embodiments, fabrication system 107 deposits a dummy gate material and planarizes the dummy gate material to form first dummy gate 314A and a second dummy gate 314B. In at least one embodiment, first dummy gate 314A and second dummy gate 314B are formed with amorphous SiGe (a-SiGe). In the embodiment, fabrication system 107 deposits layer 316 upon first dummy gate 314A and second dummy gate 314B, and deposits gate liner layer 318 upon layer 316. In particular embodiments, layer 316 and gate liner layer 318 constitute a gate hardmask. In other particular embodiments, other suitable combinations of multiple layers can be used to form a gate hardmask. In one or more embodiments, fabrication system 107 further performs gate patterning by directional RIE to transfer patterns by cutting gate liner layer 318, layer 316, first dummy gate 314A, and second dummy gate 314B to stop at conformal dummy gate oxide 312. In an embodiment, fabrication system 107 further uses a wet removal process to remove conformal dummy gate oxide 312 such that conformal dummy gate oxide 312 is self-aligned to the patterned dummy gate stack of first dummy gate 314A and second dummy gate 314B.

In block 1210, fabrication system 107 recesses portions of sacrificial layers 306A-306D, nanosheet layers 308A-308C, and substrate 304 to form a fin recess 320 between first fin 309A and second fin 309B. In a particular embodiment, fabrication system 107 forms fin recess 320 using an etching process such as by an RIE process.

In block 1212, fabrication system 107 performs a low temperature oxidation process on the fin sidewalls that oxidizes SiGe faster than Si resulting in much thicker oxide on SiGe sidewalls than that on Si sidewalls to form an oxide layer 322 on sidewalls of first fin 309A and second fin 309B. As a result, a thicker layer of oxide layer 322 is deposited on sidewalls of first dummy gate 314A, second dummy gate 314B, and sacrificial layers 306A-306D, than the thickness oxide layer 322 deposited on sidewalls of nanosheet layers 308A-308C. In a particular embodiment, a wet oxidation at a temperature of 625 degrees C. or lower is used.

In block 1214, fabrication system 107 etches back oxide layer 322 to remove oxide layer 322 from sidewalls of nanosheet layers 308A-308C while leaving a portion of oxide layer 322 on first dummy gate 314A, second dummy gate 314B, and sacrificial layers 306A-306D. As a result, first sacrificial inner spacers 323A are formed on sidewalls of first sacrificial layer 306A, second sacrificial inner spacers 323B are formed on sidewalls of second sacrificial layer 306B, third sacrificial inner spacers 323C are formed on sidewalls of third sacrificial layer 306C, and fourth sacrificial inner spacers 323D are formed on sidewalls of fourth sacrificial layer 306D, first dummy gate 314A and second dummy gate 314B. In a particular embodiment, fabrication system 107 performs an isotropic silicon oxide (SiO) etch back to remove oxide layer 322.

In block 1216, fabrication system 107 selectively deposits a spacer dielectric material 324 on the dummy gates to form first outer spacers 326A on first sacrificial inner spacers 323A, second outer spacers 326B on second sacrificial inner spacers 323B, third outer spacers 326A on third sacrificial inner spacers 323A, and fourth outer spacers 326D on fourth sacrificial inner spacers 323D. In a particular embodiment, the selective dielectric deposition deposits the spacer dielectric material only on dielectric surfaces of the sidewalls of the SiGe surfaces but not on Si surfaces of the sidewalls. In a particular embodiment, spacer dielectric material 324 is formed of SiN material.

In block 1218, fabrication system 107 forms source/drain 328 on substrate 304 within fin recess 320 between first fin 309A and second fin 309B. In a particular embodiment, fabrication system 107 forms source/drain 328 using a dual epitaxy process. In block 1220, fabrication system 107 deposits ILD 330 upon source/drain 328. In a particular embodiment, ILD 330 is formed of a silicon dioxide (SiO2) material. In block 1222, fabrication system 107 removes first dummy gate 314A and second dummy gate 314B. In block 1224, fabrication system 107 strips dummy gate oxide 312.

In block 1226, fabrication system 107 removes sacrificial layers 306A-306D. In block 1228, fabrication system 107 forms gates by forming a high-K metal gate stack (HKMG) 332 in the voids created by the removal of first dummy gate 314A, second dummy gate 314B, and sacrificial layers 306A-306D, and deposits metal gate fill layer 334 in HKMG stack 332.

In block 1230, fabrication system 107 forms an insulative cap 336 upon the gates formed by HKMG 332 and WFM 334. In a particular embodiment, insulative cap 336 is formed of a SiN material. In block 1232, fabrication system 107 forms a contact trench within ILD 330 extending to S/D 328. In block 1234, fabrication system 107 forms source/drain (S/D) contact 338 in contact with S/D 328. As a result, a nanosheet transistor is fabricated according to an illustrative embodiment. The fabrication system 107 ends process 1200 thereafter.

Thus, a computer implemented method is provided in the illustrative embodiments for fabricating nanosheet transistors in accordance with one or more illustrative embodiments and other related features, functions, or operations. Where an embodiment or a portion thereof is described with respect to a type of device, the computer implemented method, system or apparatus, the computer program product, or a portion thereof, are adapted or configured for use with a suitable and comparable manifestation of that type of device.

Where an embodiment is described as implemented in an application, the delivery of the application in a Software as a Service (SaaS) model is contemplated within the scope of the illustrative embodiments. In a SaaS model, the capability of the application implementing an embodiment is provided to a user by executing the application in a cloud infrastructure. The user can access the application using a variety of client devices through a thin client interface such as a web browser (e.g., web-based e-mail), or other light-weight client-applications. The user does not manage or control the underlying cloud infrastructure including the network, servers, operating systems, or the storage of the cloud infrastructure. In some cases, the user may not even manage or control the capabilities of the SaaS application. In some other cases, the SaaS implementation of the application may permit a possible exception of limited user-specific application configuration settings.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

1. A method of fabricating a nanosheet transistor comprising:
receiving a substrate structure including a nanosheet stack having a plurality of nanosheet layers and a plurality of sacrificial layers stacked upon a substrate, wherein the substrate structure further includes a first fin and a second fin formed in the nanosheet stack;
forming at least one dummy gate on the nanosheet stack, the at least one dummy gate being formed of an amorphous material;
recessing portions of the plurality of sacrificial layers, the plurality of nanosheet layers, and the substrate to form a fin recess between the first fin and the second fin;
performing an oxidation process to deposit an oxide layer on sidewalls of the first fin and the second fin to result in a faster oxidation of sidewalls of the sacrificial layers and the at least one dummy gate than oxidation of sidewalls the nanosheet layers;
etching the oxide layer to substantially remove the oxide layer from the sidewalls of the nanosheet layers to form at least one inner spacer on at least one sidewall of the sacrificial layers and the dummy gate; and
selectively depositing a spacer dielectric material on the at least one dummy gate to form at least one outer spacer on the at least one inner spacer.

2. The method of claim 1, wherein the plurality of nanosheet layers are formed of a silicon (Si) material.

3. The method of claim 1, wherein the plurality of sacrificial layers are formed of a silicon-germanium (SiGe) material.

4. The method of claim 1, further comprising:
forming a shallow trench isolation (STI) layer within the substrate adjacent to the first fin and the second fin.

5. The method of claim 1, wherein the amorphous material includes amorphous silicon-germanium (a-SiGe) material.

6. The method of claim 1, further comprising:
depositing a dummy gate oxide on the nanosheet stack, the dummy gate oxide disposed between the at least one gate and the nanosheet stack.

7. The method of claim 1, wherein a thicker layer of the oxide layer is deposited on the sidewalls of the at least one dummy gate and the sacrificial layers than a thickness of the oxide layer deposited on sidewalls the nanosheet layers.

8. The method of claim 1, wherein the oxidation process includes a wet oxidation at a temperature of less than or equal to 625 degrees C.

9. The method of claim 1, wherein the selective dielectric deposition deposits the spacer dielectric material only on the sidewalls of the sacrificial layers but not on the sidewalls of the nanosheet layers.

10. The method of claim 1, wherein the spacer dielectric material is formed of a silicon nitride (SiN) material.

11. The method of claim 1, wherein etching the oxide layer further includes leaving a portion of the oxide layer on the at least one dummy gate and the sacrificial layers.

12. The method of claim 1, further comprising:
forming a source/drain on the substrate within the fin recess between the first fin and the second fin.

13. The method of claim 1, further comprising:
removing the at least one dummy gate;
removing the plurality of sacrificial layers; and
forming at least one gate in voids created by removal of the at least one gate and the plurality of sacrificial layers.

14. An apparatus comprising:
a nanosheet stack having a plurality of nanosheet layers and a plurality of gate material layers stacked upon a substrate, the nanosheet stack further including a first fin and a second fin;
at least one gate formed on the nanosheet stack;
at least one inner spacer disposed on at least one sidewall of the gate material layers and the at least one gate, the at least one inner spacer formed of an oxide layer in which a thicker layer of the oxide layer is deposited on the sidewalls of the at least one gate and the gate material layers than a thickness of the oxide layer deposited on sidewalls the nanosheet layers; and
at least one outer spacer formed on the at least one inner spacer, the at least one outer spacer formed of a spacer dielectric material.

15. The apparatus of claim 14, wherein the spacer dielectric material is deposited only on the sidewalls of the gate material layers but not on the sidewalls of the nanosheet layers.

16. The apparatus of claim 14, wherein the spacer dielectric material is formed of a silicon nitride (SiN) material.

17. The apparatus of claim 14, further comprising:
a source/drain formed on the substrate between the first fin and the second fin.

18. A computer usable program product comprising one or more computer-readable storage devices, and program instructions stored on at least one of the one or more storage devices, the stored program instructions comprising:
program instructions to receive a substrate structure including a nanosheet stack having a plurality of nanosheet layers and a plurality of sacrificial layers stacked upon a substrate, wherein the substrate structure further includes a first fin and a second fin formed in the nanosheet stack;
program instructions to form at least one dummy gate on the nanosheet stack, the at least one dummy gate being formed of an amorphous material;
program instructions to recess portions of the plurality of sacrificial layers, the plurality of nanosheet layers, and the substrate to form a fin recess between the first fin and the second fin;
program instructions to perform an oxidation process to deposit an oxide layer on sidewalls of the first fin and the second fin to result in a faster oxidation of sidewalls of the sacrificial layers and the at least one dummy gate than oxidation of sidewalls the nanosheet layers;
program instructions to etch the oxide layer to substantially remove the oxide layer from the sidewalls of the nanosheet layers to form at least one inner spacer on at least one sidewall of the sacrificial layers and the dummy gate; and
program instructions to selectively deposit a spacer dielectric material on the at least one dummy gate to form at least one outer spacer on the at least one inner spacer.

19. The computer usable program product of claim 18, wherein the computer usable code is stored in a computer readable storage device in a data processing system, and wherein the computer usable code is transferred over a network from a remote data processing system.

20. The computer usable program product of claim 15, wherein the computer usable code is stored in a computer readable storage device in a server data processing system, and wherein the computer usable code is downloaded over a network to a remote data processing system for use in a computer readable storage device associated with the remote data processing system.

21. The apparatus of claim 14, wherein the gate is a dummy gate formed on the nanosheet stack.

22. The apparatus of claim 14, wherein the gate is a dummy gate formed of an amorphous material.

23. The apparatus of claim 14, further comprising:
a fin recess formed between the first fin and the second fin.

24. The apparatus of claim 14, further comprising:
a fin recess formed between the first fin and the second fin.

25. The apparatus of claim 14, further comprising:
a plurality of sacrificial layers stacked upon the substrate, wherein the oxide layer is deposited such that a faster oxidation occurs of sidewalls of the sacrificial layers and the gate than oxidation of sidewalls the nanosheet layers.

26. The apparatus of claim 25, wherein the plurality of sacrificial layers is formed of a silicon-germanium (SiGe) material.

27. The apparatus of claim 25, wherein the inner spacer is formed by substantially removing the oxide layer from the sidewalls of the nanosheet layers.

28. The apparatus of claim 14, wherein the spacer dielectric material is selectively deposited to form the outer spacer.

29. The apparatus of claim 28, wherein the outer spacer is formed on the inner spacer.

30. The apparatus of claim 14, wherein the plurality of nanosheet layers is formed of a silicon (Si) material.

31. The apparatus of claim 14, further comprising:
a shallow trench isolation (STI) layer within the substrate adjacent to the first fin and the second fin.
